(19) United States
(12) Patent Application Publication
(10) Pub. No.: US 2015/0364691 A1
(43) Pub. Date: Dec. 17, 2015

(54) INFRARED DETECTOR WITH SWNT-BASED DOUBLE-CANTILEVER AND MANUFACTURE THEREOF

(71) Applicant: South University of Science and Technology of China, Shenzhen (CN)

(72) Inventors: Fei Wang, Shenzhen, Guangdong (CN); Shaoda Zhang, Shenzhen, Guangdong (CN)

(21) Appl. No.: 14/732,830

(22) Filed: Jun. 8, 2015

(30) Foreign Application Priority Data
Jun. 12, 2014 (CN) 201410262035.2

(51) Int. Cl. H01L 51/00; H01L 51/44

(52) U.S. Cl. CPC H01L 51/0048; H01L 51/44; H01L 51/0003

(57) ABSTRACT

A double-cantilever infrared detector based on single walled carbon nanotube and the manufacture method thereof are provided. The detector comprises: a substrate having a detection window extending through the substrate from the top surface to the bottom surface; two heterogeneous cantilevers, wherein each cantilever is located on the substrate and has a fixed end connected to the substrate and a free end suspended above the detection window; a single walled carbon nanotube film bridged between the two free ends of the two heterogeneous composite cantilevers, wherein the heterogeneous cantilevers include a first material layer and a second material layer located thereon, and the first material layer and the second material layer have different thermal expansion coefficients.

The present application is based on, and claims priority from, Chinese application number 201410262035.2, filed Jun. 12, 2014, the disclosure of which is hereby incorporated by reference herein in its entirety.

### TECHNICAL FIELD

The present application relates to the field of MEMS (Micro-Electro-Mechanical System), in particular, it relates to a single walled carbon nanotube (SWNT) based double cantilever infrared detector and the production method thereof.

### BACKGROUND

In 1978, Texas Instruments (US) successfully developed the first uncooled infrared camera system in the world, wherein the main infrared material of this system is α-Si (amorphous silicon) and BST (barium strontium titanate). In 1983, Honeywell (US) started to develop a thermal detector under room temperature by means of silicon micro-machining technology, which improved the thermal isolation and reduced the cost. From 1990 to 1994, many companies in United States obtained the technology transfer from Honeywell, as a result the uncooled detector using vanadium oxide as detecting material was developed rapidly and widely. The vanadium oxide material has a relatively high thermal resistance coefficient, until so far the uncooled detector with the best performance all over the world is made of vanadium oxide material. In recent years, Raytheon company has developed and produced α-Si (amorphous silicon) thermal sensitive infrared detector on a large scale, and this kind of infrared detector occupies a certain space in the world's infrared detector market.

Single walled carbon nanotube (SWNT) is one of the hottest new materials in recent years. SWNT has different resistance values under different temperatures, it has excellent infrared absorption performance, and the noise of this material is much lower than that of other thermal sensitive materials. Therefore some scientific researchers have made high sensitive bolometers making use of this characteristic, this kind of bolometer has the advantages of low noise, high sensitivity, short response period and the like when detecting infrared ray. Further, SWNT is sensitive to the effect of stress, when there is a stress, the resistance of single walled carbon nanotube film will change significantly.

### SUMMARY

The aim of the present application is to solve one of the above technical problems. Accordingly the present application aims at providing a double-cantilever infrared detector based on single walled carbon nanotube with higher sensitivity and the manufacture method thereof.

In view of this, the present application on the one hand provides a double-cantilever infrared detector based on single walled carbon nanotube which may comprise: a substrate having a detection window arranged therein, wherein the detection window runs from the top surface to the bottom surface of the substrate; two heterogeneous cantilevers with different materials, wherein each cantilever is located on the substrate and has a fixed end connected with the substrate and a free end suspended above the detection window; a single walled carbon nanotube film bridged between two free ends of the two heterogeneous cantilevers, wherein the heterogeneous cantilevers comprise a first material layer and a second material layer arranged thereon, the thermal expansion coefficient of the first material layer is different from that of the second material layer.

When the double-cantilever infrared detector based on single walled carbon nanotube according to the embodiments of the present application is irradiated by infrared ray, the double cantilevers in the detector will deform due to thermal expansion, accordingly there is a stress force applied onto the single walled carbon nanotube film, then the resistance of the film changes, meanwhile the single walled carbon nanotube film itself has an effect on the resistance value of the film under elevated temperature. Under these dual functions, the resistance value of the single walled carbon nanotube film changes significantly, which means that the double-cantilever infrared detector according this embodiment has a relative high sensitivity to infrared ray. The double-cantilever infrared detector based on single walled carbon nanotube according to this embodiment also has the advantages of simple structure and the like.

In view of this, according to another embodiment of the present application, a method of manufacturing a double-cantilever infrared detector based on single walled carbon nanotube is provided, which may comprise the following steps: providing a substrate; forming a first material layer and a second material layer sequentially on the substrate, wherein the first and second material layers have different thermal expansion coefficients with each other; forming an aperture in the first and second material layers, wherein the aperture extends through both the bottom surface of the first material layer and the top surface of the second material layer; backside etching on the substrate, wherein the position for the backside etching corresponds to the aperture so as to form a detection window through the substrate from the top surface to the bottom surface, and form two free ends of the heterogeneous cantilevers from the first material layer and the second material layer at the parts adjacent to the aperture; forming a single walled carbon nanotube film, which is bridged between the two free ends of the heterogeneous cantilevers.

When the double-cantilever infrared detector based on single walled carbon nanotube made by the method according to the embodiments of the present application is irradiated by infrared ray, the double cantilevers inside the detector will deform due to thermal expansion, accordingly there is a stress force applied onto the single walled carbon nanotube film, as a result the resistance of the film changes, meanwhile the single walled carbon nanotube film itself has an effect on the resistance value of the film under elevated temperature. Under these dual functions, the resistance temperature coefficient of the single walled carbon nanotube film changes significantly, which means that the double-cantilever infrared detector according this embodiment has a relatively high sensitivity to infrared ray. The producing method of the double-cantilever infrared detector based on single walled carbon nanotube according to this example also has the advantages of simple process, being compatible with the existing MEMS technology and the like.

### BRIEF DESCRIPTION OF THE DRAWINGS

FIG. 1 is a schematic diagram of the double-cantilever infrared detector based on the single walled carbon nanotube according to an embodiment of the present application.

FIG. 2 is a schematic diagram of the double-cantilever infrared detector based on the single walled carbon nanotube according to another embodiment of the present application.

FIG. 3 is a flow chart of a forming method of the double-cantilever infrared detector based on the single walled carbon nanotube according to an embodiment of the present application.

FIG. 4 is a flow chart of a forming method of the double-cantilever infrared detector based on the single walled carbon nanotube according to another embodiment of the present application.

FIGS. 5a-5f are the process flow diagrams of a forming process of the double-cantilever infrared detector based on the single walled carbon nanotube according to an embodiment of the present application.

### DETAILED DESCRIPTION OF THE INVENTION

The embodiment of the present application will be described in detail in the following description, and the specific examples are illustrated in the accompanying figures, wherein the same or similar reference numbers indicate the same or similar elements of the elements with the same or similar function. The following described examples with reference to the figures are only illustrated and used to explain the present disclosure but not to limit the present application.

According to an embodiment of the present application, a double-cantilever infrared detector based on single walled carbon nanotube is provided.

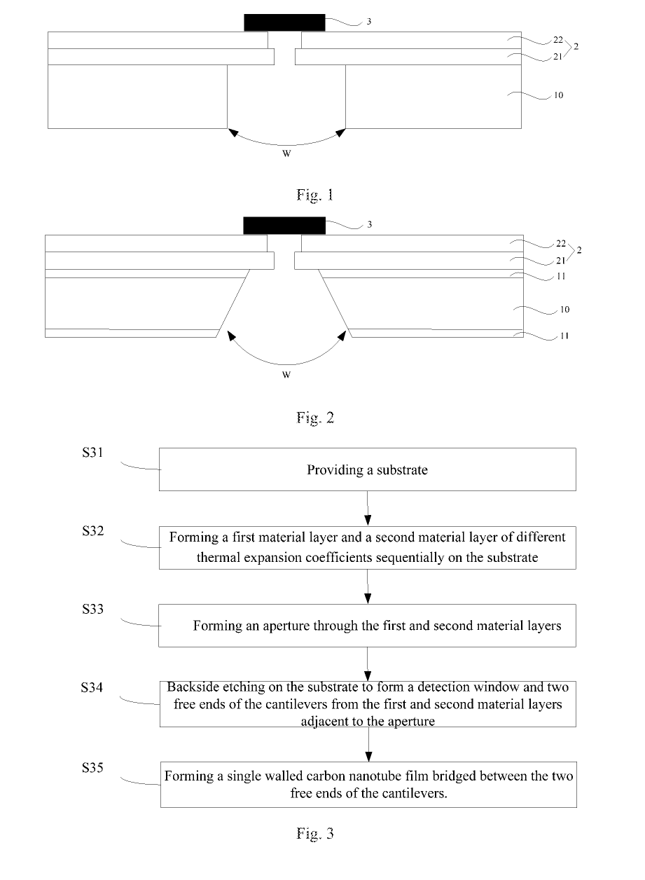

FIG. 1 is a schematic diagram of the double-cantilever infrared detector based on the single walled carbon nanotube according to an embodiment of the present application. As shown in FIG. 1, the infrared detector comprises: a substrate 10, two heterogeneous cantilevers 2 and a single walled carbon nanotube film 3. There is a detection window W extending through the substrate 10 from the top surface to the bottom surface thereof. Both heterogeneous cantilevers 2 are located on the substrate 10 sequentially and each cantilever 2 has a fixed end connected to the substrate 10 and a free end suspended at the place of detection window W. The single walled carbon nanotube film 3 is bridged between the two free ends of the two heterogeneous composite cantilevers 2, wherein the heterogeneous cantilevers 2 include a first material layer 21 and a second material layer 22 located thereon, and the first material layer 21 and the second material layer 22 have different coefficient of thermal expansion (CTE) with each other.

The operation principle of the double-cantilever infrared detector based on single walled carbon nanotube according to this embodiment is: when the detector is arranged in an environment to be detected, the infrared ray in the environment will irradiate onto the free ends of the heterogeneous cantilevers 2 and the single walled carbon nanotube film 3 through detection window W. Because the heterogeneous cantilevers 2 consist of a first material layer 21 and a second material layer 22 of different thermal expansion coefficients, the first material layer 21 and the second material layer 22 will have different elongation quantities under the thermal effect of the infrared, and the heterogeneous cantilever 2 has a deformation, then the two heterogeneous cantilevers 2 draw the single walled carbon nanotube film 3 simultaneously and they all have deformation so as to generate a force onto the single walled carbon nanotube film, accordingly the resistance of the single walled carbon nanotube film 3 changes. Meanwhile the single walled carbon nanotube film 3 itself has a relatively high temperature coefficient of resistance (TCR). Under the dual superimposed functions of the stress generated by deformation and the temperature influence, the single walled carbon nanotube film has a significant variation on the resistance value, which means the double-cantilever infrared detector of this embodiment has very high sensitivity. The double-cantilever infrared detector based on single walled carbon nanotube according to this embodiment also has the advantage of simple structure.

FIG. 2 is a schematic diagram of the double-cantilever infrared detector based on the single walled carbon nanotube according to another embodiment of the present application. As shown in FIG. 2, the double-cantilever infrared detector of this embodiment further comprises a passivation layer 11. The passivation layer 11 is located between the substrate 10 and the two heterogeneous cantilevers 2, and also arranged on the bottom surface of the substrate 10. The passivation layer 11 has an insulation protective function to the substrate 10.

In order to converge the infrared ray in a better way onto the free ends of the two heterogeneous cantilevers 2 and onto the single walled carbon nanotube film 3 in the infrared detector, the detection window W can be configured to have a shape with top area being larger than the bottom area, for example a frustum or truncated pyramid with a smaller top and a larger bottom, as shown in the detection window W in FIG. 2.

In order to make each of the two heterogeneous cantilevers 2 have a significant flexural deflection under thermal expansion, it is preferable that the first material layer 21 and the second material layer 22 have remarkably different thermal expansion coefficients with each other. According to a preferable embodiment, the first material layer 21 is a SiO₂ layer, and the second material layer 22 is an Au layer. According to another embodiment the second material layer 22 is an Al layer. It should be acknowledged that other infrared absorbing layer of smaller thermal expansion coefficient and other metal layer of larger thermal expansion coefficient can be selected.

The following table 1 shows the parameters of different materials suitable to be the first material layer or the second material layer.

TABLE 1
parameters of different candidate materials

| | | | Expansion | Thermal | Specific | |
|---|---|---|---|---|---|---|
| | Young's | Pois- | Coeffi- | Conduc- | heat | |
| | Modulus | son | cient | tivity | (J/(Kg | Density |
| | (GPa) | Ratio | (10⁻⁶ K⁻¹) | (W/(cm K)) | K)) | (g/cm³) |
| Au | 78 | 0.42 | 14.2 | 3.2 | 132 | 19.3 |
| NiCr | 200 | 0.312 | 13.3 | 0.907 | 440 | 8.9 |
| Poly-Si | 169 | 0.22 | 2.9 | 1.5 | 753 | 2.33 |
| SiNx | 300 | 0.26 | 3.2 | 0.35 | 333 | 2.44 |
| SiO₂ | 70 | 0.17 | 0.5 | 0.011 | 227 | 2.2 |
| SiC | 415 | 0.16 | 1.1 | 0.013 | 715 | 3.16 |

In Table 1, Poisson's ratio is the negative ratio of transverse to axial strain. When a material is compressed in one direction, it usually tends to expand in the other two directions perpendicular to the direction of compression. This phenomenon is called the Poisson effect, and Poisson's ratio is a measure of this effect. The Poisson ratio is the fraction (or percent) of expansion divided by the fraction (or percent) of compression, for small values of these changes.

In order to obtain a better film quality, the single walled carbon nanotube film 3 can be made by two-dimensional electrophoresis. The single walled carbon nanotube film made by two-dimensional electrophoresis employs simple equipment, has low cost, and the film forms quickly, it is suitable for large scale production, and the obtained film has uniform thickness, the material and solution in the electrophoresis deposition can be recycled, they have no acid or base contaminant to discharge, so the process of film production has the advantage of environmental protection.

According to a second aspect of the present application, a double-cantilever infrared detector based on single walled carbon nanotube is provided.

FIG. 3 is a flow chart of a forming method of the double-cantilever infrared detector based on the single walled carbon nanotube according to an embodiment of the present application. As shown in FIG. 3, the forming method of the double-cantilever infrared detector based on the single walled carbon nanotube according to this embodiment comprises the following steps:

S31: Providing a substrate.

S32: Forming a first material layer and a second material layer sequentially on the substrate, wherein the first and second material layers have different thermal expansion coefficients with each other.

It should be noted that the areas of the first material layer 21 and the second material layer 11 are smaller than the area of the substrate, respectively, and the specific size of the area is determined by the dimensions of cantilever.

S33: Forming an aperture in the first and second material layers, wherein the aperture extends through both the bottom surface of the first material layer and the top surface of the second material layer.

It should be understood that the aperture may be formed by one-step process (i.e., after the first material layer and the second material layer are formed, an aperture extending through these two layers is formed in one-step processing), it also can be formed in a two-step method (i.e. form an opening in the first material layer after this layer is formed, then forming another opening in the second layer after this layer is formed). The specific process depends on the material characteristics of the first material layer and the second material layer.

S34: Backside etching on the substrate, wherein the position for the backside etching corresponds to the aperture so as to form a detection window through the substrate from the top surface to the bottom surface, and to form two free ends of the heterogeneous cantilevers from the first material layer and the second material layer adjacent to the aperture;

S35: Forming a single walled carbon nanotube film, which is bridged between the two free ends of the two heterogeneous cantilevers.

When the double-cantilever infrared detector based on single walled carbon nanotube made by the method according to the embodiments of the present application is irradiated by infrared ray, the double cantilevers inside the detector will deform due to thermal expansion, accordingly there is a stress force applied onto the single walled carbon nanotube film, as a result the resistance value of the film varies, meanwhile the single walled carbon nanotube film itself has an effect on the resistance value of the film under elevated temperature. Under these dual functions, the resistance temperature coefficient of the single walled carbon nanotube film changes significantly, which means that the double-cantilever infrared detector according this embodiment has a relative high sensitivity. The forming method of the double-cantilever infrared detector based on single walled carbon nanotube according to this example also has the advantages of simple process, being compatible with the existing MEMS technology and the like.

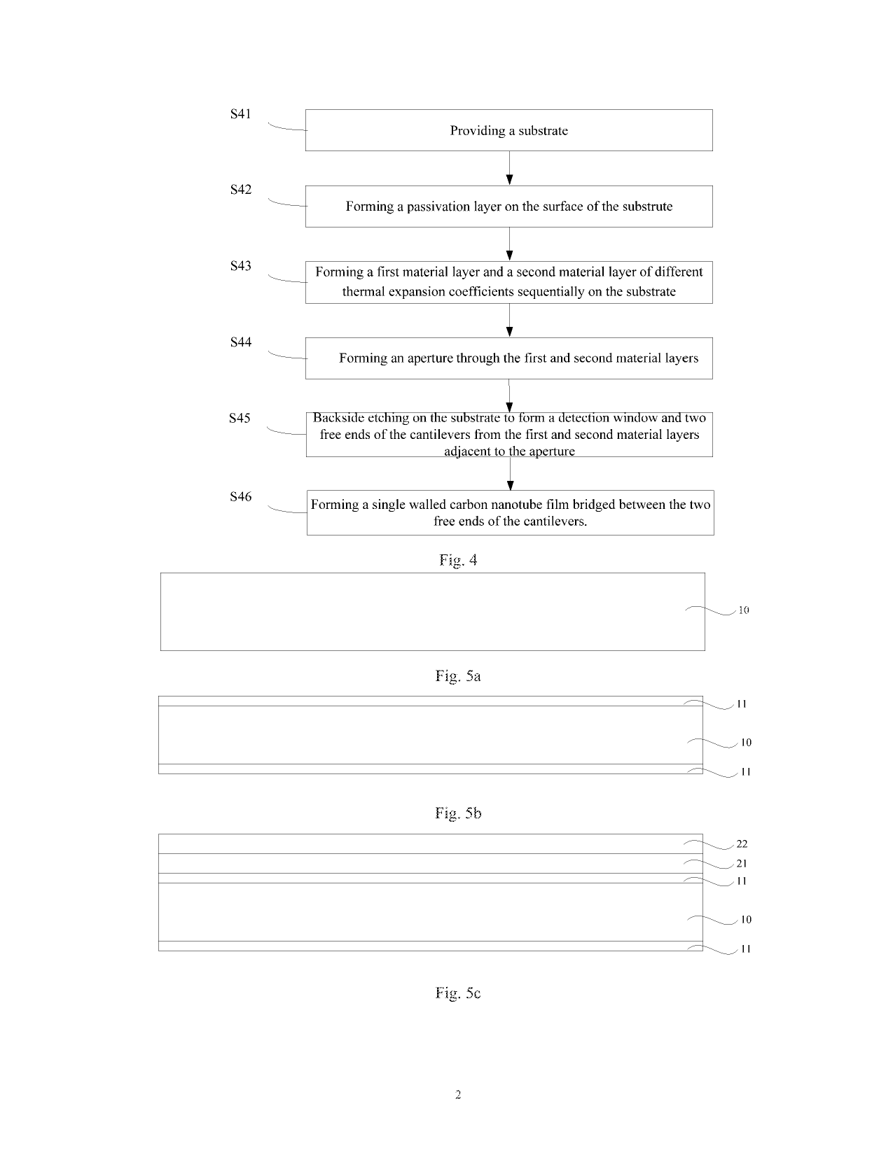

FIG. 4 is a flow chart of a forming method of the double-cantilever infrared detector based on the single walled carbon nanotube according to another embodiment of the present application. As shown in FIG. 4, the forming method according to this embodiment further comprises the following step: forming a passivation layer on the surface of the substrate before the formation of the first and second layers. The passivation layer has an insulation protective function to the substrate.

In order to converge the infrared ray in a better way onto the free ends of the two heterogeneous cantilevers and onto the single walled carbon nanotube film of the infrared detector, the detection window can be configured to have a shape of top area being larger than the bottom area, for example a frustum or truncated pyramid with a smaller top and a larger bottom.

In order to make each heterogeneous cantilever have a significant flexural deflection under thermal expansion, it is preferable that the first material layer and the second material layer have remarkably different thermal expansion coefficients with each other. According to a preferable embodiment, the first material layer 21 is made of SiO₂, and the second material layer 22 is made of Au. It should be acknowledged that other infrared absorbing layer of smaller thermal expansion coefficient and other metal layer of larger thermal expansion coefficient can be selected.

In order to obtain a better film quality, the single walled carbon nanotube film can be made by two-dimensional electrophoresis. The single walled carbon nanotube film made by two-dimensional electrophoresis employs simple equipment, has low cost, and the film forms quickly, it is suitable for large scale production, and the obtained film has uniform thickness, the material and solution in the electrophoresis deposition can be recycled, they have no acid or base contaminant to discharge, so the process of film production has the advantage of environmental protection.

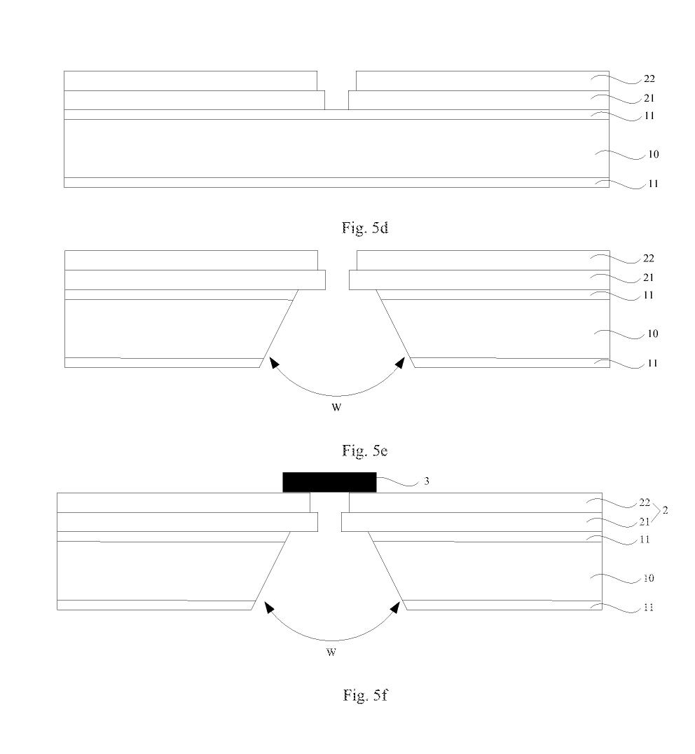

In order to illustrate the double-cantilever detector based on single walled carbon nanotube of the present application and the manufacture method thereof in detail, now a specific example is given below with reference to FIGS. 5a to 5f:

As shown in FIG. 5a, a substrate 10 of single crystal silicon is provided, and it is washed and dried for later use.

As shown in FIG. 5b, the substrate 10 is oxidized to obtain a deactivation layer 11 of silicon dioxide. For example, the deactivation layer 11 can be formed by the process of low-pressure chemical vapor deposition (LPCVD) under 1100° C., and the obtained deactivation layer 11 has a thickness of approximate 500 nm.

As shown in FIG. 5c, a first material layer 21 and second material layer 22 are formed on the deactivation layer 11 sequentially on the top of the substrate 10, each of them has a length of about 120 μm, and a width of about 40 μm. The first material layer 21 may be made of silicon dioxide (SiO₂), and can be formed by plasma enhanced chemical vapor deposition (PECVD), it has a thickness of approximate 500 nm. The second material layer 22 can be made of Au or Al and can be formed by electron beam evaporator deposition, it has a thickness of approximate 200 nm.

As shown in FIG. 5d, the aperture is disposed at the center of the first material layer 21 and the second material layer 22. Because these two materials have significantly different properties with each other, the aperture should be obtained in two steps but not one step. For instance, the Au is patterned by reactive ion etching (RIE) process to obtain an aperture in the second material layer 22, wherein the etching gas can be a mixed gas of Cl₂ and BCl₃. Then the mixed gas of SF₆ and He is used as an etching gas to perform deep reactive ion etching (DRIE) on the first materials layer 21 to form an aperture therein. It should be noticed that the aperture width of the first material layer 21 may be equivalent to the aperture width of the second material layer 22, alternatively, the aperture width of the first material layer 21 may be smaller than that of the second material layer 22. The aperture width determines the distance between the electrophoresis electrodes of the following method of making single walled carbon nanotube film by double electrophoresis process. In this embodiment, the aperture has a width of 15 nm.

As shown in FIG. 5e, the bottom of the substrate 10 is etched from backside, so as to obtain a detection window W. In particular, the deactivation layer 11 on the bottom of the substrate 10 can be first processed by lithographic printing process to form an etched pattern, wherein the location of this pattern corresponds to the aperture position formed in the proceeding process step. Then the silicon oxide in the area of the etched pattern is removed by DRIE process, as a result the area on the bottom of the substrate 10 without being covered with the passivation layer 11 is exposed. Then the exposed area of the substrate 10 is subject to wet chemical etching with a solution of Tetramethylammonium Hydroxide (TMAH) to remove the silicon material. Because the wet chemical etching has the characteristic of isotropic, an etched pot hole (this pot hole is the precursor of the detection window) with a larger area of bottom than the top area is easily obtained. After that the DRIE process is continued so as to remove the local part of the deactivation layer 11 on the top of the substrate 10, and a detection window W extending through the substrate 10 from the top surface to the bottom surface can be obtained, at the same time the first material layer 21 and the second material layer 22 adjacent to the aperture turn into two free ends of the heterogeneous cantilevers 2.

As shown in FIG. 5f, a single walled carbon nanotube film 3 is formed between the two free ends of the two heterogeneous composite cantilevers 2 by electrophoresis, so the single walled carbon nanotube film 3 is bridged between the two free ends. In particular, 1 mg of single walled carbon nanotube (SWNT) powder is first added into 100 ml solution of 1% (w/w) sodium dodecyl sulfate (SDS), and the obtained solution is sonicated for 2-3 hours, then centrifuged at 12000 rpm for 10 min to skim undispersed SWNT, the upper suspension is kept for later use. Using the two ends of the two gold layers across the aperture as the electrophoresis electrodes, and a DC electric field of 1 MHz frequency and 10 Vp-p amplitude is loaded across the two electrodes. When the prepared suspension is dropwise added into the space between the two gold electrodes, the SWNT will move towards the electrodes on both sides under the electric field because of its dielectrophoresis (DEP) property. Finally a part of the SWNT in the suspension moves to the vicinity of both electrodes, and the remaining part of the SWNT still stays at the space between the two electrodes, so as to form a spread water meniscus of crescent moon shape. The collected single walled carbon nanotube is adhered onto the gold point under surface tension and compression. The obtained single walled carbon nanotube film 3 has a thickness of about 15 μm. Accordingly, a double-cantilever infrared detector based on single walled carbon nanotube is obtained.

The double-cantilever infrared detector based on single walled carbon nanotube made by the above process is tested under the temperatures of from 20° C. to 80° C. The test results show that the SiO₂/Au heterogeneous cantilever is under the dual superimposed functions of infrared radiation and stress after the flexure due to the absorption of infrared radiation, and the temperature coefficient of resistance (TCR) of the single walled carbon nanotube film is 3.17% K⁻¹. TCR refers to the rate of change of the resistance value when the temperature rises 1. Under the same environment without SiO₂ absorption layer and only under the effect of infrared radiation, the temperature coefficient of resistance of the single walled carbon nanotube film is 1.85% K⁻¹. It can be seen that, the double-cantilever infrared detector based on single walled carbon nanotube according to the present application has higher sensitivity.

When the carbon nanotube is bent under force, the change of the resistance of this carbon nanotube is determined, the result shows that its electric conductivity decreases by almost two orders of magnitude when the strain increases from 0% to 3.2%. Many scientists think that the change of resistance with stress is due to the changes on the bonding of partial carbon atoms, that is the SP² turns into SP³ structure, when the static pressure increases from 0 to 1.5 Gpa its resistance reduces by about 10%, and the change is reversible. It is known that when a carbon nanotube is under a stress, its structure changes so the energy gap changes, therefore the increased stress on the semiconductor carbon nanotube increased its resistance.

Further, the thermal conductivity in axial direction of a carbon nanotube is different from that in radial direction, wherein the axial thermal conductivity is as high as that of diamond, but the radial thermal conductivity is relatively low. The single walled carbon nanotube has a relatively high resistance temperature coefficient. Its resistance will decrease sharply as the temperature increases, and its TCR value is negative, therefore it has high sensitivity when employed in uncooled infrared detectors.

In the description of the present disclosure, it should be understood that the terms for indicating orientation or position relationship such as “center”, “length”, “width”, “thickness”, “upper”, “lower”, “top”, “bottom”, “inside”, and “outside” are only used for describing the orientation or position shown in the Figures, and only to facilitate the description and simplify this description, but not to indicate or imply that the said device or element must be in the specific orientation and have the specific structure and under the specific operation, therefore there is no intention to make any limitation to the present application.

Furthermore, the terms “first”, “second” are only used for description, but not intended to indicate or imply the relative importance or implicitly indicate that the number of the described technical features. Thus, the features with the limitation of “first”, or “second” may explicitly or implicitly include at least one of the feature. In the description of the present application, the expression “a plurality of” means the number is at least two, such as two, three, or the like, unless otherwise expressly specified.

The embodiments above-mentioned are merely the preferable ones of the present application and not intended to limit the present application. And all changes, equivalent substitution and improvements which come within the meaning and range of equivalency of the present application are intended to be embraced therein.

1. A double-cantilever infrared detector based on single walled carbon nanotube comprising:
a substrate having a detection window extending through the substrate from a top surface to a bottom surface;
two heterogeneous cantilevers, wherein each of the cantilevers is located on the substrate and has a fixed end connected to the substrate and a free end suspended above the detection window;
a single walled carbon nanotube film bridged between two free ends of the two heterogeneous cantilevers,
wherein the heterogeneous cantilevers comprise a first material layer and a second material layer arranged thereon, the first material layer is made of SiO₂, and the second material layer is made of Au.

2. The double-cantilever infrared detector of claim 1, wherein the detection window has a top area smaller than a bottom area thereof.

3. The double-cantilever infrared detector of claim 1, wherein the single walled carbon nanotube film is formed by two-dimensional electrophoresis.

4. The double-cantilever infrared detector of claim 1, further comprises:
a passivation layer located between the substrate and the two heterogeneous cantilevers, and also arranged on the bottom surface of the substrate.

5. A method for producing a double-cantilever infrared detector based on single walled carbon nanotube comprising:
providing a substrate;
forming a first material layer and a second material layer sequentially on the substrate, wherein the first material layer is made of SiO₂, and the second material layer is made of Au;
forming an aperture in the first and second material layers, wherein the aperture extends from the bottom surface of the first material layer to the top surface of the second material layer;
backside etching on the substrate, wherein the position for the backside etching corresponds to the aperture so as to form a detection window through the substrate from the top surface to the bottom surface, and form two free ends of the heterogeneous cantilevers from the first material layer and the second material layer adjacent to the aperture;
forming a single walled carbon nanotube film, which is bridged between the two free ends of the heterogeneous cantilevers.

6. The method of claim 5, wherein the detection window has a top area smaller than a bottom area thereof.

7. The method of claim 5, wherein the single walled carbon nanotube film is made by two-dimensional electrophoresis.

8. The method of claim 5, further comprising:
forming a deactivation layer on the surface of the substrate prior to the formations of the first layer and the second layer.
